(19) United States
(12) Patent Application Publication
(10) Pub. No.: US 2002/0033536 A1
(43) Pub. Date: Mar. 21, 2002

(54) Semiconductor device and manufacturing method thereof

(76) Inventors: Kwan-Ju Koh, Seoul (KR); Jae-Seung Kim, Seoul (KR); Hong-Seub Kim, Seoul (KR)

Correspondence Address: Skjerven Morrill Macpherson LLP, Suite 700, 25 Metro Drive, San Jose, CA, 95110, US

(21) Appl. No.: 09/947,458

(22) Filed: Sep. 5, 2001

(30) Foreign Application Priority Data
Sep. 5, 2000 (KR) 2000-52261

(51) Int. Cl. H01L 23/48; H01L 23/52; H01L 29/40

(52) U.S. Cl. 257/758

(57) ABSTRACT

A semiconductor element comprises an insulating layer formed on a semiconductor substrate; a plurality of windows formed in the insulating layer, exposing predetermined portions of the semiconductor substrate; epitaxial silicon layers formed on the insulating layer and within the windows, the epitaxial silicon layers being separated at predetermined areas; and semiconductor devices, each formed on one of the epitaxial silicon layers. The method for manufacturing a semiconductor element comprises forming an insulating layer on a silicon wafer and selectively etching the insulating layer to form a plurality of windows that expose the silicon wafer; forming an epitaxial silicon layer over an entire surface of the insulating layer by performing an epitaxial growth process; selectively etching the epitaxial silicon layer to separate the same at predetermined areas between the windows, thereby realizing a plurality of epitaxial silicon layers; and forming individual semiconductor devices on each of the epitaxial silicon layers.

### BACKGROUND OF THE INVENTION

(a) Field of the Invention

The present invention relates to a semiconductor device and a manufacturing method thereof, and more particularly, to a semiconductor device and a manufacturing method thereof in which a selective epitaxial growth method is used to isolate devices.

(b) Description of the Related Art

Device isolation techniques play an important role in the design and performance of highly integrated semiconductor circuits by electrically isolating regions and device therein from adjacent devices and regions. Moreover, as the degree of integration in semiconductor circuits increase, there is a concomitant need to develop techniques for forming isolation regions which are free of defects and can be scaled to provide isolation regions having smaller dimensions, but without sacrificing the isolation capability of the regions.

One widely used and relatively simple technique for providing device isolation is typically referred to as local oxidation of silicon (LOCOS). Unfortunately, this technique has a number of disadvantages because it typically includes the formation of bird's beak oxide extensions, induces lattice stress which can lead to the formation of crystal defects in semiconductor substrates, and causes redistribution of channel-stop dopants. As will be understood by those skilled in the art, these disadvantages typically cause a reduction in the lateral area available for active devices, and degrade the reliability and performance of devices formed in adjacent active regions.

Another method, which may be considered an improvement over the LOCOS method, is typically referred to as the shallow trench isolation (STI) method. In the STI method, a device isolation region is established by selectively etching a semiconductor substrate to form trenches therein and then filling the trenches with an electrically insulating region (e.g., oxide). A chemical etching and/or chemical mechanical polishing (CMP) step can then be performed to planarize the electrically insulating region to be level with the surface of the substrate. Because the STI method typically does not include a lengthy thermal oxidation step as typically required by the LOCOS method, many of the disadvantages of the LOCOS method can be eliminated to some degree.

FIG. 1 shows a schematic sectional view of a conventional semiconductor device using STI method.

As shown in the drawing, a trench is formed in a semiconductor isolation region of a semiconductor substrate 1, and a field oxide layer 2 is formed in the trench. Further, a gate including a gate oxide layer 3 and a gate polysilicon layer 4 is formed in a device region of the semiconductor substrate 1. A spacer 6, which is made of an electrically insulating material, is formed along side walls of the gate, and a LDD (lightly doped drain) 5 is formed under the spacer 6 in the semiconductor substrate 1. The LDD 5 is doped at a low concentration with impurities of an opposite conductivity as the semiconductor substrate 1. A source/drain 7 is formed adjacent to the LDD 5 in the semiconductor substrate 1. The source/drain 7 is doped at a high concentration with impurities of the same conductivity as the LDD 5 (i.e., the opposite conductivity as the semiconductor substrate 1). The gate and the source/drain 7 form a MOS (metal oxide semiconductor) transistor.

A PMD (pre-metal dielectric) 9 is formed over the above devices provided on the semiconductor substrate 1. The PMD 9 includes contact holes that expose portions of the source/drain 7 and the gate, and tungsten plugs 10 are provided in the contact holes. Also, a metal wiring layer 11 is formed on the PMD 9 in a state contacting the tungsten plugs 10. Finally, provided on an upper surface of the gate polysilicon layer 4 and the source/drain 7, that is, on a surface of these devices that contact the tungsten plugs 10, are silicide layers 8.

In the conventional semiconductor device described above, if the contact holes are formed by selectively etching the PMD 9 in accordance with increases in the integration of the semiconductor device, misalignment occurs as a result of a reduction in space provided for performing the processes. Therefore, the field oxide layer 2 at a trench edge portion is etched such that the semiconductor substrate 1 is exposed at the device isolation region as shown in area “a” of FIG. 1. This results in the formation of a leakage current path such that errors occur in the operation of the device. If design is performed to provide a sufficient amount of space in order to remedy this problem, a reduction in device integration results.

### SUMMARY OF THE INVENTION

The present invention has been made in an effort to solve the above problems.

It is an object of the present invention to provide a semiconductor device and a manufacturing method thereof, in which device isolation is performed such that a sufficient contact space is provided without experiencing a drop in device integration.

To achieve the above object, the present invention provides a semiconductor element and a manufacturing method thereof. The semiconductor element comprises an insulating layer formed on a semiconductor substrate; a plurality of windows formed in the insulating layer and which expose predetermined portions of the semiconductor substrate; epitaxial silicon layers formed on the insulating layer and within the windows, the epitaxial silicon layers being separated at predetermined areas; and semiconductor devices, each formed on one of the epitaxial silicon layers.

According to a feature of the present invention, the insulating layer is an oxide layer.

According to another feature of the present invention, the insulating layer is formed at a thickness of between 4000 Å and 6000 Å.

According to yet another feature of the present invention, the angle formed between the portion of the insulating layer defining the windows and an upper surface of the semiconductor substrate is between 70 and 80 degrees.

According to still yet another feature of the present invention, a thickness of the epitaxial silicon layers is between 500 Å and 1000 Å.

The method for manufacturing a semiconductor element comprises the steps of forming an insulating layer on a silicon wafer and selectively etching the insulating layer to form a plurality of windows that expose the silicon wafer; forming an epitaxial silicon layer over an entire surface of the insulating layer by performing an epitaxial growth process using the silicon wafer exposed through the windows, and performing a planarizing process of the epitaxial silicon layer; selectively etching the epitaxial silicon layer to separate the same at predetermined areas between the windows, thereby realizing a plurality of epitaxial silicon layers; and forming individual semiconductor devices on each of the epitaxial silicon layers.

According to a feature of the present invention, in the step of forming an insulating layer on a silicon wafer and selectively etching the insulating layer to form a plurality of windows that expose the silicon wafer, a plurality of window patterns are formed on the insulating layer, and exposed portions of the insulating layer are reactive ion etched using the window patterns as a mask such the windows are formed at a predetermined angle with respect to the silicon wafer.

According to another feature of the present invention, the predetermined angle is between 70 and 80 degrees.

According to yet another feature of the present invention, in the step of forming an insulating layer on a silicon wafer and selectively etching the insulating layer to form a plurality of windows that expose the silicon wafer, the insulating layer is realized through a thermal oxide layer formed by thermally oxidizing the silicon wafer.

According to still yet another feature of the present invention, in the step of forming an insulating layer on a silicon wafer and selectively etching the insulating layer to form a plurality of window that expose the silicon wafer, the insulating layer is realized through an oxide layer formed by CVD process

According to still yet another feature of the present invention, the insulating layer is formed at a thickness of between 4000 Å and 6000 Å.

According to still yet another feature of the present invention, in the step of forming an epitaxial silicon layer over an entire surface of the insulating layer by performing an epitaxial growth process using the silicon wafer exposed through the windows, and performing a planarizing process of the epitaxial silicon layer, a thickness of the epitaxial silicon layer is between 500 Å and 1000 Å.

According to still yet another feature of the present invention, the planarizing of the epitaxial silicon layer is performed using a CMP process.

### BRIEF DESCRIPTION OF THE DRAWINGS

The accompanying drawings, which are incorporated in and constitute a part of the specification, illustrate an embodiment of the invention, and, together with the description, serve to explain the principles of the invention:

FIG. 1 is a schematic sectional view of a conventional MOS transistor;

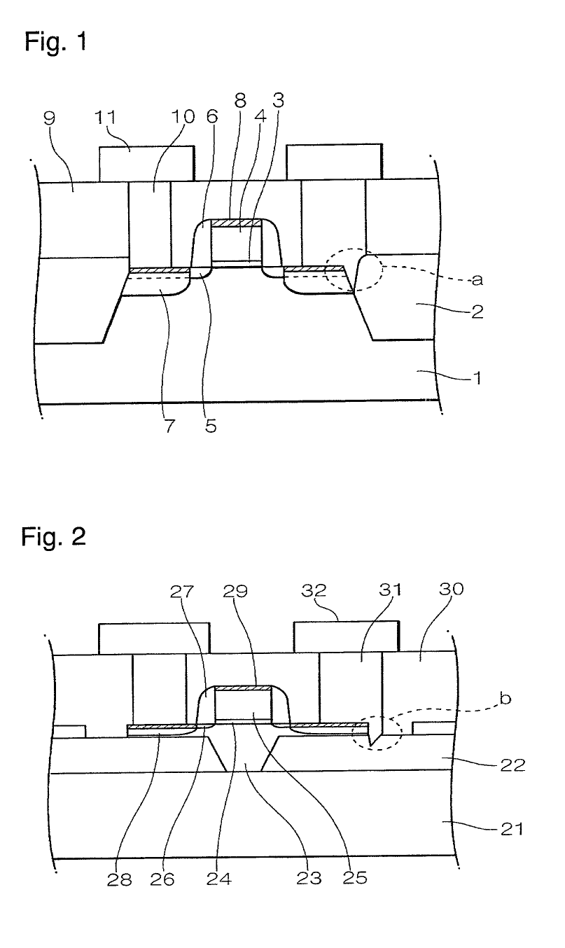

FIG. 2 is a schematic sectional view of a MOS transistor according to a preferred embodiment of the present invention; and

FIGS. 3a-3e are schematic sectional views of the MOS transistor of FIG. 2 as it undergoes sequential manufacturing processes.

### DETAILED DESCRIPTION OF THE PREFERRED EMBODIMENTS

Preferred embodiments of the present invention will now be described in detail with reference to the accompanying drawings.

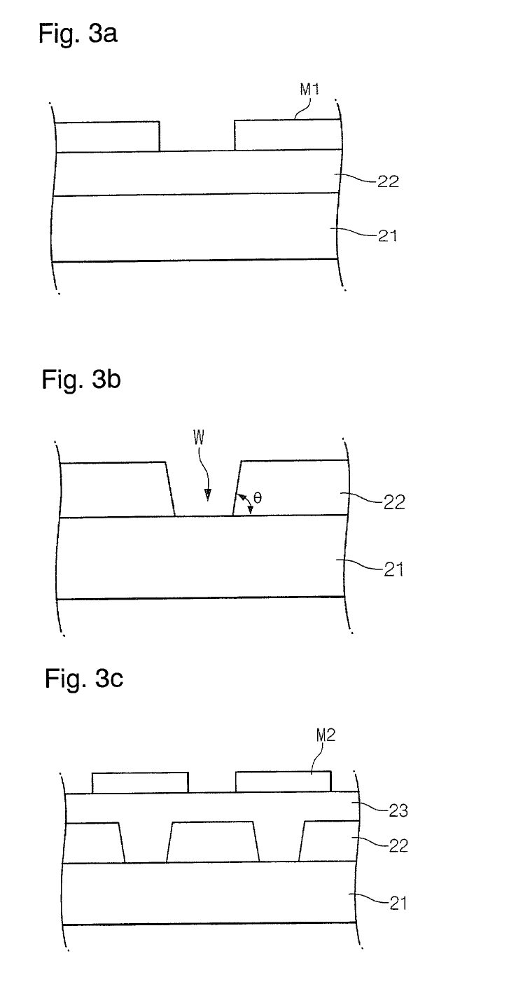

FIG. 2 shows a schematic sectional view of a MOS transistor according to a preferred embodiment of the present invention.

With reference to the drawing, a plurality of windows are defined in an insulating layer 22 which is formed on a semiconductor substrate 21. A plurality of epitaxial silicon layers 23 are formed in a separated state on the insulating layer 22, that is at locations corresponding to the windows of the insulating layer 22 such that the epitaxial silicon layers 23 fill the windows.

A MOS transistor is formed on each epitaxial silicon layer 23. In more detail, a gate that includes a gate oxide layer 24 and a gate polysilicon layer 25 is formed on each epitaxial silicon layer 23. A spacer 27 is formed along side walls of each pair of the gate polysilicon layer 25 and the gate oxide layer 24, and a LDD 26 is formed in each epitaxial silicon layer 23 under the spacer 27. The LDDs 26 are doped at a low concentration. Further, a source/drain 28, which is doped at a high concentration with impurities of the same conductivity as the LDDs 26, is formed in regions adjacent to the epitaxial silicon layers 23.

A PMD 30 is formed on the epitaxial silicon layers 23 and on exposed portions of the insulating layer 22. The PMD 30 insulates each electrode of the MOS transistors from a metal wiring layer 32 (to be described hereinafter). Also, the PMD 30 includes contact holes for exposing portions of each electrode of the MOS transistors, and tungsten plugs 31 are provided in the contact holes. As a result, electrical contact between element electrodes and the metal wiring layer 32 is realized.

The metal wiring layer 32 is provided on the PMD 30 and formed in a metal thin film pattern that contacts the tungsten plugs 31. Also, silicide layers 29 are formed on each gate polysilicon layer 25 and source/drain 28. The silicide layers 29 act to reduce contact resistance.

Unlike conventional device isolation using STI method, in the semiconductor device of the present invention, after the epitaxial silicon layers grown on the insulating layer are separated, the MOS transistors are formed on the epitaxial silicon layers such that device isolation of each cell formed by the MOS transistors is realized by the insulating layer. Accordingly, with the inventive semiconductor device, even if an edge portion of the device isolation regions is etched during contact hole formation as a result of misalignment, the device isolation insulating layer is exposed rather than the semiconductor substrate as shown by area “b” of FIG. 2. Therefore, leakage of current is prevented such that yield is improved, and a sufficient design margin is provided to enable increased integration

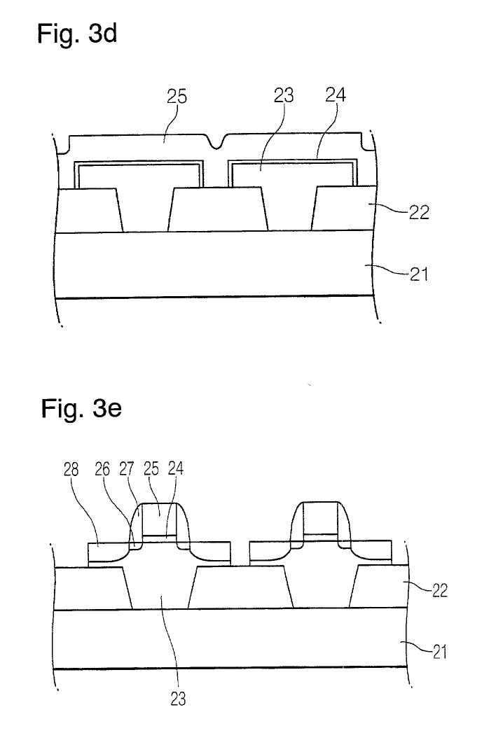

FIGS. 3a-3e show schematic sectional views of the MOS transistor of FIG. 2 as it undergoes sequential manufacturing processes.

First, with reference to FIG. 3a, the insulating layer 22 is formed on the silicon wafer (semiconductor substrate) 21 at a predetermined thickness, preferably between 4000 Å and 6000 Å. The insulating layer 22 acts as an device isolator, and can be realized, for example, through a thermal oxide layer in which the silicon wafer 21 is thermally oxidized, or through an oxide layer that is formed on the silicon wafer 21 using chemical vapor deposition (CVD) process. Next, a plurality of window patterns M1 are formed on the insulating layer 22. The window patterns M1 may be formed by depositing a photosensitive layer on the insulating layer 22, then exposing the photosensitive layer using a mask formed to realize the window patterns M1, after which develop is performed.

Next, with reference to FIG. 3b, exposed portions of the insulating layer 22 are etched using the window patterns M1 as a mask such that there are formed a plurality of windows W for selective epitaxial growth. The windows W expose portions of the silicon wafer 21. After the windows W are formed, the window patterns M1 are removed. At this time, it is preferable that reactive ion etching (RIE) is used to etch the insulating layer 22. Further, it is preferable that an angle θ formed between an upper surface of the silicon wafer 21 and the portion of the insulating layer 22 defining the windows W is between 70 and 80 degrees such that epitaxial growth, performed hereinafter, is smoothly realized.

Subsequently, with reference to FIG. 3c, an epitaxial silicon layer 23 is formed over an entire surface of the insulating layer 22. That is, a selective epitaxial growth process using portions of the silicon wafer 21 exposed through the windows W of the insulating layer 22 is performed such that the epitaxial silicon layer 23 is grown on the insulating layer 22 and within the windows W. The grown epitaxial silicon layer 23 is then planarized. At this time, it is preferable that the epitaxial layer 23 is between 500 Å and 1000 Å, and that a chemical mechanical polishing (CMP) process is used for the planarizing process.

Next, mask patterns M2 that are used for semiconductor device isolation are formed on the planarized epitaxial silicon layer 23. The mask patterns M2 may be formed by depositing a photosensitive layer on the epitaxial silicon layer 23, then exposing the photosensitive layer using a mask formed to realize the mask patterns M2, after which develop is performed.

After the above, with reference to FIG. 3d, selective patterning of the epitaxial silicon layer 23 is performed, that is portions of the epitaxial silicon layer 23 exposed by the mask patterns M2 are etched, such that the epitaxial silicon layer 23 is separated between each window area to thereby realize device isolation through the formation of a plurality of epitaxial silicon layers 23. Next, the mask patterns M2 are removed. The epitaxial silicon layers 23 are then thermally oxidized to form the gate oxide layers 24, and a polysilicon layer 25 is deposited over all exposed elements.

With reference to FIG. 3e, the polysilicon layer 25 and the gate oxide layers 24 are patterned to form a gate for a MOS transistor on each epitaxial silicon layer 23. That is, a gate pattern is formed on the polysilicon layer 25, and portions of the polysilicon layer 25 exposed through a mask are etched to form the plurality of the gate polysilicon layers 25, and the exposed gate oxide layers 24 are etched. Next, the epitaxial silicon layers 23 that are exposed using the gate polysilicon layers 25 as masks are ion injected with impurities at a low concentration to form the LDDs 26.

Next, an insulating layer is deposited over all exposed elements and etched to form the spacers 27 along the gate oxide layers 24 and the gate polysilicon layers 25. The spacers 27 and the gate polysilicon layers 25 are then used as masks and the epitaxial silicon layers 23 are ion injected at a high concentration with impurities of the same conductivity as the LDDs 26 to form the source/drains 28. Therefore, the individual elements of the MOS transistors are completed.

Next, referring again to FIG. 2, using conventional salicide processes, silicide layers 29 are formed on upper surfaces of the gate polysilicon layers 25 and the source/drains 28. Following this process, a PMD 30 is formed over all exposed elements to insulate the MOS transistors from the metal wiring layer 32 and planarized. The PMD 30 is then selectively etched to form contact holes for exposing portions of the gate polysilicon layers 25 and the source/drains 28, that is the silicide layers 29 formed on these elements. Metal plugs, preferably the tungsten plugs 31, are provided in the contact holes such that the element electrodes and the metal wiring layer 32 are in contact. Finally, a thin metal film is deposited and patterned on the PMD 30 to form the metal wiring layer 32, which contacts the tungsten plugs 31, thereby completing the semiconductor device as shown in FIG. 2.

In the semiconductor element of the present invention as described above, an device isolation insulating layer having a plurality of windows is formed on the semiconductor substrate, and the epitaxial silicon layers are grown and patterned using the windows such that epitaxial silicon layers are separated between the window regions, thereby realizing device isolation. Accordingly, even if an edge portion of the isolation regions is etched during contact hole formation as a result of misalignment, the device isolation insulating layer is exposed rather than the semiconductor substrate. Therefore, the leakage of current is prevented such that yield is improved, and a sufficient design margin is provided to enable increased integration.

Although preferred embodiments of the present invention have been described in detail hereinabove, it should be clearly understood that many variations and/or modifications of the basic inventive concepts herein taught which may appear to those skilled in the present art will still fall within the spirit and scope of the present invention, as defined in the appended claims.

What is claimed is:

1. A semiconductor device comprising:
an insulating layer formed on a semiconductor substrate;
a plurality of windows formed in the insulating layer and which expose predetermined portions of the semiconductor substrate;
epitaxial silicon layers formed on the insulating layer and within the windows, the epitaxial silicon layers being separated at predetermined areas; and
semiconductor devices, each formed on one of the epitaxial silicon layers.

2. The semiconductor device of claim 1 wherein the insulating layer is an oxide layer.

3. The semiconductor device of claim 1 wherein the insulating layer is formed at a thickness of between 4000 Å and 6000 Å.

4. The semiconductor device of claim 1 wherein the angle formed between the portion of the insulating layer defining the windows and an upper surface of the semiconductor substrate is between 70 and 80 degrees.

5. The semiconductor device of claim 1 wherein a thickness of the epitaxial silicon layers is between 500 Å and 1000 Å.

6. A method for manufacturing a semiconductor device comprising the steps of:
forming an insulating layer on a silicon wafer and selectively etching the insulating layer to form a plurality of windows that expose the silicon wafer;
forming an epitaxial silicon layer over an entire surface of the insulating layer by performing an epitaxial growth process using the silicon wafer exposed through the windows, and performing a planarizing process of the epitaxial silicon layer;
selectively etching the epitaxial silicon layer to separate the same at predetermined areas between the windows, thereby realizing a plurality of epitaxial silicon layers; and
forming individual semiconductor devices on each of the epitaxial silicon layers.

7. The method of claim 6 wherein in the step of forming an insulating layer on a silicon wafer and selectively etching the insulating layer to form a plurality of windows that expose the silicon wafer, a plurality of window patterns are formed on the insulating layer, and exposed portions of the insulating layer are reactive ion etched using the window patterns as a mask such the windows are formed at a predetermined angle with respect to the silicon wafer.

8. The method of claim 7 wherein the predetermined angle is between 70 and 80 degrees.

9. The method of claim 6 wherein in the step of forming an insulating layer on a silicon wafer and selectively etching the insulating layer to form a plurality of windows that expose the silicon wafer, the insulating layer is realized through a thermal oxide layer formed by thermally oxidizing the silicon wafer.

10. The method of claim 6 wherein in the step of forming an insulating layer on a silicon wafer and selectively etching the insulating layer to form a plurality of window that expose the silicon wafer, the insulating layer is realized through an oxide layer formed by CVD process.

11. The method of claim 9 wherein the insulating layer is formed at a thickness of between 4000 Å and 6000 Å.

12. The method of claim 6 wherein in the step of forming an epitaxial silicon layer over an entire surface of the insulating layer by performing an epitaxial growth process using the silicon wafer exposed through the windows, and performing a planarizing process of the epitaxial silicon layer, a thickness of the epitaxial silicon layer is between 500 Å and 1000 Å.

13. The method of claim 12 wherein the planarizing of the epitaxial silicon layer is performed using a CMP process.
